(19) United States
(12) Patent Application Publication
(10) Pub. No.: US 2009/0102001 A1
(43) Pub. Date: Apr. 23, 2009

(54) Image Sensor and a Method for Manufacturing Thereof

(76) Inventor: Kang Hyun Lee, Yongin-si (KR)

Correspondence Address: SALIWANCHIK LLOYD & SALIWANCHIK;A PROFESSIONAL ASSOCIATION, PO Box 142950, GAINESVILLE, FL, 32614, US

(21) Appl. No.: 12/249,999

(22) Filed: Oct. 13, 2008

(30) Foreign Application Priority Data
Oct. 22, 2007 (KR) 10-2007-0105939

(51) Int. Cl. H01L 31/0232; H01L 31/18

(52) U.S. Cl. 257/432; 438/69; 257/E31.127

(57) ABSTRACT

An image sensor according to an embodiment includes a semiconductor substrate including a photodiode; a protective layer pattern having a lower trench that is disposed on the semiconductor substrate to expose the photodiode; an insulating layer pattern having the upper trench that is disposed on the lower trench of the protective layer pattern to expose the photodiode; and a wave guide that is disposed in the lower trench and the upper trench.

### CROSS-REFERENCE TO RELATED APPLICATION

The present application claims the benefit under 35 U.S.C. §119 of Korean Patent Application No. 10-2007-0105939, filed Oct. 22, 2007, which is hereby incorporated by reference in its entirety.

### BACKGROUND

An image sensor is a semiconductor device that converts an optical image into an electrical signal. Image sensors are generally classified as charge coupled device (CCD) image sensors and complementary metal oxide semiconductor (CMOS) image sensors.

The CMOS image sensor utilizes a photodiode and a MOS transistor within a unit pixel to sequentially detect electrical signals of each unit pixel using a switching scheme, implementing an image.

In the CMOS image sensor, as the design rule is gradually reduced, a size of a unit pixel is reduced, which can reduce photo sensitivity. In order to increase the photo sensitivity, a microlens is often formed on the color filter.

However, the photo sensitivity can also be reduced by diffraction and scattering of light due to structures, such as lines, existing in an optical path from the microlens to the photodiode.

### BRIEF SUMMARY

Embodiments of the present invention provide an image sensor and a method for manufacturing thereof capable of improving light condensing rate.

An image sensor according to an embodiment comprises a semiconductor substrate including a photodiode; a protective layer pattern having a lower trench that is disposed on the semiconductor substrate to expose the photodiode; an insulating layer pattern having an upper trench that is disposed on the lower trench of the protective layer pattern to expose the photodiode; and a wave guide that is disposed in the lower trench and the upper trench.

A method for manufacturing an image sensor according to an embodiment comprises: forming a photodiode on a semiconductor substrate; forming a protective layer on the semiconductor substrate; forming an insulating layer on the protective layer; forming a protective layer pattern and an insulating layer pattern by etching the protective layer and the insulating layer to form a trench exposing a surface of the photodiode; and forming a wave guide in the trench.

### BRIEF DESCRIPTION OF THE DRAWINGS

FIGS. 1 to 5 are process cross-sectional views showing a process for manufacturing an image sensor according to the embodiment.

### DETAILED DESCRIPTION

An image sensor and a method for manufacturing thereof according to the present invention will be described with reference to the accompanying drawings.

It is to be understood that the figures and descriptions of embodiments of the present invention have been simplified to illustrate elements that are relevant for a clear understanding of the invention, while eliminating, for purposes of clarity, other elements that may be well known. Those of ordinary skill in the art will recognize that other elements may be desirable and/or required in order to implement the present invention. However, because such elements are well known in the art, and because they do not facilitate a better understanding of the present invention, a discussion of such elements is not provided herein.

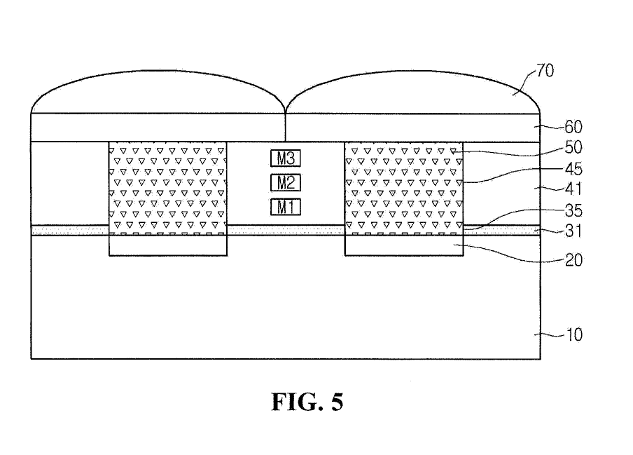

Referring to FIG. 5, an image sensor according to an embodiment can include a photodiode 20 disposed on a semiconductor substrate 10 for each unit pixel.

A protective layer pattern 31 having a lower trench 35 to expose the photodiode 20 is disposed on the semiconductor substrate 10.In an embodiment, the protective layer pattern 31 can be formed of a nitride film.

An insulating layer pattern 41 having an upper trench 45 to expose the photodiode 20 is disposed on the protective layer pattern 31. The upper trench 45 can be formed to have the same width as the lower trench 35 to expose the photodiode 20.

The insulating layer pattern 41 can be formed in a plurality of layers. In certain embodiments, the insulating layer pattern 41 can be formed to include an oxide film, such as silicon dioxide (SiO₂), silane (SiH₄), tetraethyl-orthosilicate (TEOS), boro-phospho-silicate glass (BPSG), undoped-silicate glass (USG), or fluorosilicate glass (FSG).

A plurality of metal lines M1, M2, and M3 can be formed in the insulating layer pattern 41 at regions not covering the photodiode 20.

Wave guides 50 can be disposed inside the lower trench 35 and the upper trench 45. The wave guide 50 can be formed of a material having higher refractive index than those of the insulating layer pattern 41 and the protective pattern 31 to condense light in the photodiode 20. For example, the wave guide 50 can be formed of materials, such as spin on glass (SOG), hydrogen-silsesquioxane (HSQ), and polymer.

A color filter 60 and a microlens 70 can be disposed on the semiconductor substrate 10 including the wave guide 50 and the insulating layer pattern 41 for each unit pixel.

With the image sensor according to an embodiment, a waveguide having higher refractive index than that of an interlayer insulating layer is positioned on the upper of the photodiode, making it possible to improve the light condensing rate of the photodiode.

Also, the waveguide is disposed for each unit pixel, making it possible to inhibit cross talk between pixels.

Also, the microlens is disposed on the waveguide, making it possible to improve the light condensing rate.

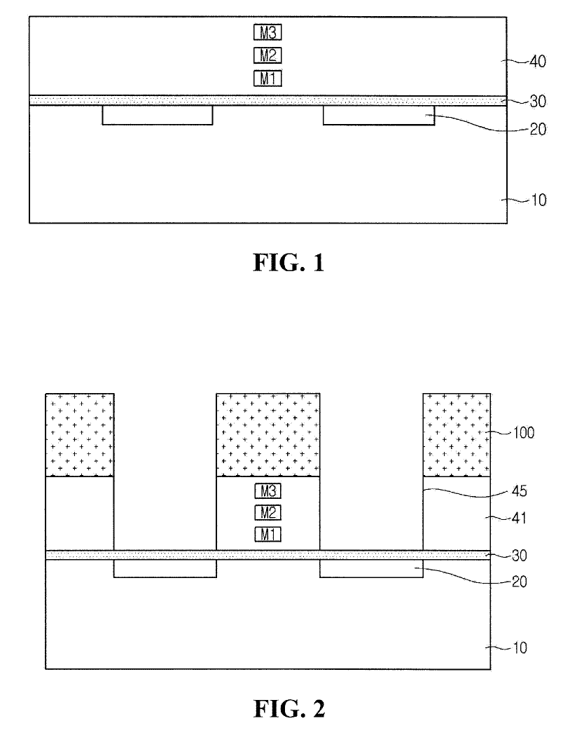

A method for manufacturing an image sensor will be described with reference to FIGS. 1 to 5.

Referring to FIG. 1, a protective layer 30 can be formed on a semiconductor substrate 10 including a photodiode 20.

The photodiode 20, which receives light to generate photo charges, can be formed on the semiconductor substrate 10 for each unit pixel. Although not shown, a transistor which is connected to the photodiode 20 and converts the received photo charges into the electrical signals can be formed on the semiconductor substrate for each unit pixel.

The protective layer 30, which is for protecting the surface of the photodiode 20, can be formed, for example, of a nitride film.

An insulating layer 40 including the metal lines M1, M2, and M3 can be formed on the protective layer 30. The insulating layer 40 can be formed in a plurality of layers.

In an embodiment, the insulating layer 40 can be formed of an oxide film, such as SiO₂, SiH₄, TEOS, BPSG, USG, and FSG.

The metal lines M1, M2, and M3 can be formed in a plural numbers by penetrating the insulating layer 40. The metal lines M1, M2, and M3 can be formed to be intentionally arranged not to cover the photodiode 20.

Referring to FIG. 2, an insulating layer pattern 41 having an upper trench 45 can be formed on the semiconductor substrate 10. The insulating layer pattern 41 can expose the surface of the protective layer 30 corresponding to the photodiode 20 and cover the remaining areas.

In order to form the insulating layer pattern 41, a photoresist pattern 100 exposing the surface of the insulating layer 40 at a region corresponding to the photodiode 20 can be formed on the insulating layer 40. An etching process can be performed on the insulating layer 40 by using the photoresist pattern 100 as an etching mask. In an embodiment, an anisotropic etching using a reactive ion etching process can be performed. At this time, the protective layer 30 can perform a role of an etch stop layer.

Accordingly, an upper trench 45 is formed on the protective layer 30 at a region corresponding to the photodiode 20. In addition, in the etching process for the insulating layer 40 the protective layer 30 can be provided on the photodiode 20, such that the photodiode 20 can avoid an etching damage by the plasma during the etching of the insulating layer 40.

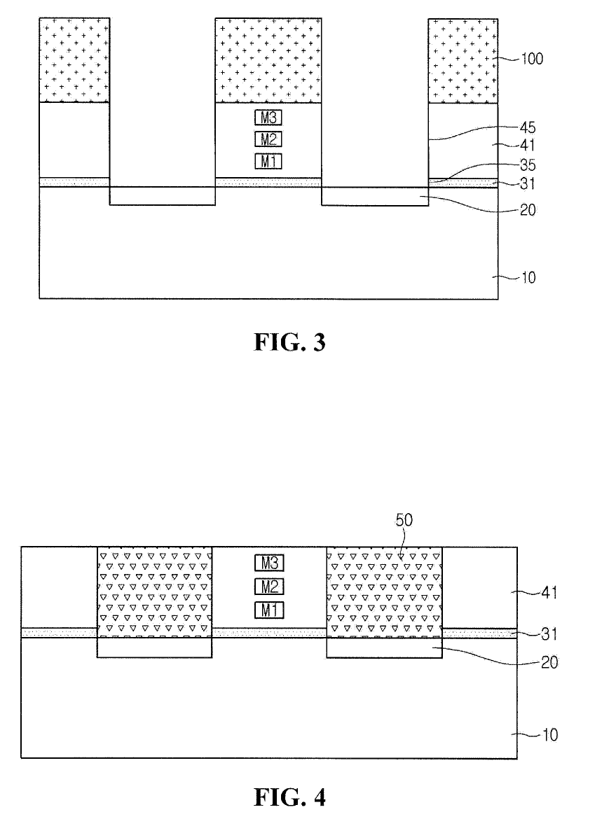

Referring to FIG. 3, the protective layer pattern 31 exposing the surface of the photodiode 20 can be formed. The protective layer pattern 31 includes a lower trench 35 exposing the photodiode 20.

In order to form the protective layer pattern 31, an etching process can be performed on the protective layer 30 by using the photoresist pattern 100 as the etching mask. In an embodiment, an isotropic etching using a chemical dry etching can be performed to etch the protective layer 30. In one embodiment, the chemical dry etching process can be performed under a pressure of 100 to 1000 mTorr using CₓF_{y} based gas (carbon-fluorine based gas) and a u-wave. Therefore, the chemical dry etching process can be performed on the protective layer 30 so that plasma is not generated, making it possible to inhibit the damage to the surface of the photodiode 20.

Then, the photoresist pattern 100 can be removed and the protective layer pattern 31 and the insulating layer pattern 41 exposing the photodiode remain on the semiconductor substrate 10.

Referring to FIG. 4, a waveguide 50 can be formed in the upper trench 45 and the lower trench 35. The waveguide 50 can condense light to the photodiode 20.

The wave guide 50 can be formed by filling materials having higher refractive index than that of the insulating layer pattern 41 within the upper trench 45 and the lower trench 35. In certain embodiments, the waveguide 50 can be formed by filling materials into the trench, such as SOG, HSQ, or polymer.

The waveguide 50 can be formed on the upper surface of the photodiode 20 through the upper trench 45 and the lower trench 35. Accordingly, the incident light can be condensed to the photodiode 20 by the waveguide 50.

Referring to FIG. 5, a color filter 60 and a microlens 70 can be formed on the semiconductor substrate 10 including the waveguide 50 and the insulating layer pattern 41 for each unit pixel.

Each color filter 60 can be formed according to unit pixel, making it possible to separate color from incident light. For example, red, green, and blue color filters can be formed.

The color filters 60 can be formed by performing a spin coating process with materials for the color filter, including photosensitive material and pigment or photosensitive material and dye. Then, the materials for the color filter are exposed and developed by the pattern mask to form the color filter 60.

The microlenses 70 can be formed for each unit pixel for further condensing light to the photodiode 20 disposed below.

The microlenses 70 can be formed by applying the silicon oxide film having high light transmittance or a photosensitive photoresist and then performing a patterning process to form a lens pattern corresponding to the photodiode 20 disposed for each unit pixel. Then, a reflow process can be performed on the lens pattern to form the microlenses 70 having a dome shape.

With a method for manufacturing an image sensor according to an embodiment, a waveguide is formed inside of the insulating layer to correspond to the photodiode, making it possible to improve the light condensing rate of the photodiode. In other words, the waveguide is formed on the upper area of the photodiode to inhibit the diffractive and scattering of light by the insulating layer, making it possible to condense light to the photodiode.

Also, the wave guide is formed on the upper of the photodiode formed for each unit pixel, making it possible to reduce cross talk.

The microlens can be formed on the wave guide so that the incident light is doubly collected in the photodiode through the microlens and the wave guide, making it possible to improve the fill factor.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An image sensor comprising:
a semiconductor substrate including a photodiode;
a protective layer pattern on the semiconductor substrate and comprising a lower trench disposed to expose the photodiode;
an insulating layer pattern on the protective layer pattern and comprising an upper trench disposed above the lower trench to expose the photodiode; and
a wave guide disposed in the lower trench and the upper trench.

2. The image sensor according to claim 1, wherein the protective layer pattern comprises a nitride film and the insulating layer pattern comprises an oxide film.

3. The image sensor according to claim 1, wherein the waveguide comprises a material having higher refractive index than that of the insulating layer pattern.

4. The image sensor according to claim 1, wherein the waveguide comprises spin on glass (SOG), hydrogen-silsesquioxane (HSQ), or polymer.

5. The image sensor according to claim 1, further comprising a microlens on the insulating layer pattern including the waveguide.

6. The image sensor according to claim 5, wherein the microlens covers the waveguide and a portion of the insulating layer pattern adjacent the waveguide.

7. The image sensor according to claim 1, further comprising a color filter on the insulating layer pattern including the waveguide.

8. The image sensor according to claim 7, further comprising a microlens on the color filter.

9. A method for manufacturing an image sensor, comprising:
forming a photodiode on a semiconductor substrate;
forming a protective layer on the semiconductor substrate;
forming an insulating layer on the protective layer;
forming an insulating layer pattern comprising an upper trench in a region corresponding to the photodiode by etching the insulating layer;
forming a protective layer pattern comprising a lower trench in the region corresponding to the photodiode by etching the protective layer to expose a surface of the photodiode; and
forming a wave guide in the upper trench and the lower trench.

10. The method according to claim 9, wherein the wave guide contacts the exposed surface of the photodiode.

11. The method according to claim 9, wherein forming the insulating layer pattern comprises:
forming a photoresist pattern on the insulating layer; and
performing an anisotropic etching process using the photoresist pattern as a mask to form the upper trench exposing the protective layer.

12. The method according to claim 11, wherein forming the protective layer pattern comprises:
performing an isotropic etching process on the protective layer using the photoresist pattern as a mask to form the lower trench exposing the surface of the photodiode.

13. The method according to claim 12, wherein performing the isotropic etching process on the protective layer comprises performing a chemical dry etching method using a carbon-fluorine based gas.

14. The method according to claim 12, wherein the protective layer comprises a nitride film and the insulating layer comprises an oxide film.

15. The method according to claim 9, wherein the waveguide comprises a material having higher refractive index than the protective layer and the insulating layer.

16. The method according to claim 9, wherein the waveguide comprises spin on glass (SOG), hydrogen-silsesquioxane (HSQ), or polymer.

17. The method according to claim 9, further comprising forming a microlens on the insulating layer pattern including the waveguide to correspond to the photodiode.

18. The method according to claim 9, further comprising forming a color filter on the insulating layer pattern including the waveguide to correspond to the photodiode.
